(19) United States
(12) Patent Application Publication
(10) Pub. No.: US 2024/0292640 A1
(43) Pub. Date: Aug. 29, 2024

(54) INFRARED IMAGE SENSOR AND MANUFACTURING METHOD THEREOF

(71) Applicant: Samsung Electronics Co., Ltd., Suwon-si (KR)

(72) Inventors: Yunki LEE, Suwon-si (KR); Soongju OH, Seoul (KR); Byungku JUNG, Seoul (KR); Hyeyeon PARK, Suwon-si (KR)

(73) Assignees: Samsung Electronics Co., Ltd., Suwon-si, Gyeonggi-do (KR); Korea University Research and Business Foundation, Seoul (KR)

(21) Appl. No.: 18/586,789

(22) Filed: Feb. 26, 2024

(30) Foreign Application Priority Data
Feb. 27, 2023 (KR) 10-2023-0026186

(51) Int. Cl. H10K 39/32

(52) U.S. Cl. CPC H10K 39/32

(57) ABSTRACT

An image sensor including a semiconductor substrate including a first surface and a second surface opposite to the first surface, an anti-reflection layer on the first surface of the semiconductor substrate, and a photoelectric converter configured to absorb incident light incident through the semiconductor substrate and photoelectrically convert the incident light. The semiconductor substrate includes a refraction pattern on the first surface of the semiconductor substrate and configured to refract the incident light.

### CROSS-REFERENCE TO RELATED APPLICATION

This application is based on and claims priority under 35 U.S.C. § 119 to Korean Patent Application No. 10-2023-0026186, filed on Feb. 27, 2023, in the Korean Intellectual Property Office, the disclosure of which is incorporated by reference herein in its entirety.

### BACKGROUND

The inventive concepts relate to image sensors, and more particularly, to infrared image sensors and manufacturing methods thereof.

An image sensor is a device that converts an optical image signal into an electrical signal. The image sensor receives light incident on the semiconductor substrate at a photodiode area within the semiconductor substrate and converts it into an electrical signal. In particular, in an image sensor that detects infrared rays, the infrared absorption rate of an infrared absorbing semiconductor is relatively low, resulting in increased noise and reduced sensitivity of the image sensor.

### SUMMARY

Some example embodiments of the inventive concepts provide an image sensor and/or manufacturing method thereof, in which productivity is improved and stability is improved by reducing cost.

In addition, the problem to be solved by the technical idea of the inventive concepts is not limited to the above-mentioned problems, and other problems may be clearly understood by those skilled in the art from the description below.

According to some example embodiments of the inventive concepts, an image sensor may include a semiconductor substrate including a first surface and a second surface opposite to the first surface, an anti-reflection layer on the first surface of the semiconductor substrate, and a photoelectric converter configured to absorb incident light incident through the semiconductor substrate and photoelectrically convert the incident light. The semiconductor substrate may include a refraction pattern on the first surface of the semiconductor substrate and configured to refract the incident light.

According to some example embodiments of the inventive concepts, an image sensor may include a semiconductor substrate including a first surface and a second surface opposite to the first surface, an anti-reflection layer on the first surface of the semiconductor substrate, an interlayer insulating layer between the semiconductor substrate and the anti-reflection layer, and a photoelectric converter configured to absorb incident light incident through the semiconductor substrate and photoelectrically convert the incident light. The photoelectric converter may include an electron transport layer on the second surface of the semiconductor substrate, an absorption layer on the electron transport layer, and a hole transport layer on the absorption layer. The semiconductor substrate may include a refraction pattern on the first surface of the semiconductor substrate, the refraction pattern contacting the interlayer insulating layer.

According to some example embodiments of the inventive concepts, an image sensor may include a semiconductor substrate including a first surface and a second surface opposite to the first surface, an anti-reflection layer on the first surface of the semiconductor substrate, an interlayer insulating layer between the semiconductor substrate and the anti-reflection layer; and a photoelectric converter configured to absorb incident light incident through the semiconductor substrate and photoelectrically convert the incident light. The photoelectric converter may include an electron transport layer on the second surface of the semiconductor substrate, an absorption layer on the electron transport layer, and a hole transport layer on the absorption layer. The absorption layer may be configured to absorb infrared rays incident on the first surface of the semiconductor substrate, and the absorption layer may include at least one of PbS, PbSe, InAs, InGaAs, AgSe, or CaTiO. The semiconductor substrate may include a refraction pattern on the first surface of the semiconductor substrate and in contact with the interlayer insulating layer. The refraction pattern may include any one of a triangular shape, a square shape, a lens shape, or a wave pattern shape.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram illustrating an image sensor according to some example embodiments;

FIG. 2 is a circuit diagram illustrating pixels included in an image sensor according to some example embodiments;

FIG. 3 is a schematic perspective view of an image sensor according to some example embodiments;

FIGS. 4A, 4B, 4C, 4D, and 4E are enlarged views of area AX shown in FIG. 3 according to some example embodiments;

FIG. 5 is a flowchart illustrating a method of manufacturing an image sensor, according to some example embodiments;

FIGS. 6A, 6B, 6C, 6D, 6E, 6F, 6G, 6H, and 6I are cross-sectional views illustrating a method of manufacturing an image sensor, according to some example embodiments;

FIG. 7 is a block diagram of an electronic device including a multi-camera module, according to some example embodiments;

FIG. 8 is a detailed block diagram of the camera module of FIG. 7, according to some example embodiments; and

FIG. 9 is a block diagram illustrating the configuration of an image sensor according to some example embodiments.

### DETAILED DESCRIPTION

Hereinafter, some example embodiments of the present inventive concepts are described in detail with reference to the accompanying drawings. The same reference numerals are used for the same components in the drawings, and descriptions already given for them are omitted.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for case of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

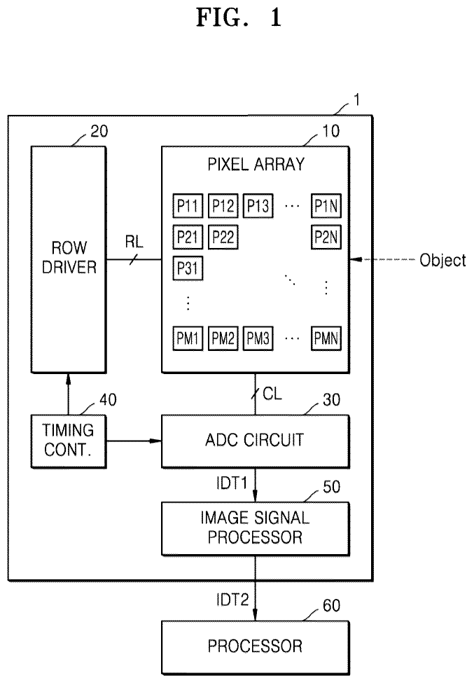

FIG. 1 is a block diagram illustrating an image sensor 1 according to some example embodiments.

Referring to FIG. 1, the image sensor 1 according to some example embodiments may be mounted in an electronic device having an image or light sensing function. For example, the image sensor 1 may be applied to electronic devices, such as cameras, smartphones, wearable devices, Internet of Things (IOT), tablet personal computers (PCs), personal digital assistants (PDAs), portable multimedia players (PMPs), navigation devices, and the like. In addition, the image sensor 1 may be employed in vehicles, furniture, manufacturing facilities, doors, and various measuring devices.

The image sensor 1 may include a pixel array 10, a row driver 20, an analog-to-digital conversion circuit 30 (hereinafter referred to as an ADC circuit), a timing controller 40, and an image signal processor 50.

The pixel array 10 may receive an optical signal from an object and convert the optical signal into an electrical signal. The pixel array 10 may be implemented as a quantum dot image sensor but is not limited thereto.

The pixel array 10 includes a plurality of row lines RL, a plurality of column lines CL (or referred to as output lines), and a plurality of pixels P11, P12, P13, . . . , PIN, P21, P22, . . . , P2N, P31, . . . PM1, PM2, PM3, . . . PMN, hereinafter P11 to PMN) which are connected to the plurality of row lines RL and the plurality of column lines CL and arranged in M rows and N columns. In this example, the number of pixels P11 to PMN may be M×N, where “M” and “N” may each independently be any integer.

Each of the plurality of pixels P11 to PMN may sense a received optical signal (e.g., incident light) by using a photoelectric converter. The plurality of pixels P11 to PMN may detect the amount (e.g., intensity) of light of the optical signal and output an electrical signal representing the amount of detected light.

The row driver 20 may generate a plurality of control signals capable of controlling the operation of the pixels P11 to PMN arranged in each row under the control of the timing controller 40. The row driver 20 may provide a plurality of control signals to each of the plurality of pixels P11 to PMN of the pixel array 10 through a plurality of row lines RL. In response to a plurality of control signals provided from the row driver 20, the pixel array 10 may be driven row-by-row.

Under the control of the row driver 20, the pixel array 10 may output a plurality of sensing signals through a plurality of column lines CL.

The analog-to-digital conversion (ADC) circuit 30 may perform analog-to-digital conversion on each of a plurality of sensing signals received through a plurality of column lines CL to generate and output first image data IDT1. The ADC circuit 30 may include an ADC corresponding to each of the plurality of column lines CL, and the ADC may convert a sensing signal received through a corresponding column line CL into a pixel value. Depending on to the operation mode of the image sensor 1, the pixel value may represent the amount of light sensed by the plurality of pixels P11 to PMN.

The ADC circuit 30 may include a correlated double sampling (CDS) circuit for sampling and holding a received signal. The CDS circuit may double-sample a noise signal and a sensing signal when the plurality of pixels P11 to PMN are in a reset state and output a signal corresponding to the difference between the sensing signal and the noise signal. The ADC may include a counter, and the counter may generate pixel values by counting signals received from the CDS circuit. For example, the CDS circuit may be implemented with an operational transconductance amplifier (OTA), a differential amplifier, or the like. The counter may be implemented with, for example, an up-counter and an arithmetic circuit, an up/down counter, and a bit-wise inversion counter.

The timing controller 40 may generate timing control signals that control operations of the row driver 20 and the ADC circuit 30. The row driver 20 and the ADC circuit 30 may drive the pixel array 10 row-by-row, as described above, based on the timing control signals output from the timing controller 40 and may convert a plurality of sensing signals received through a plurality of column lines CL into pixel values.

The image signal processor 50 may receive the first image data IDT1, for example, raw image data, from the ADC circuit 30 and perform signal processing on the first image data IDT1 to generate and output second image data IDT2. The image signal processor 50 may perform signal processing, such as black level compensation, lens shading compensation, crosstalk compensation, and bad pixel compensation.

The second image data IDT2 output from the image signal processor 50, for example, signal-processed image data, may be transmitted to the processor 60. The processor 60 may be a host processor of an electronic device in which the image sensor 1 is mounted.

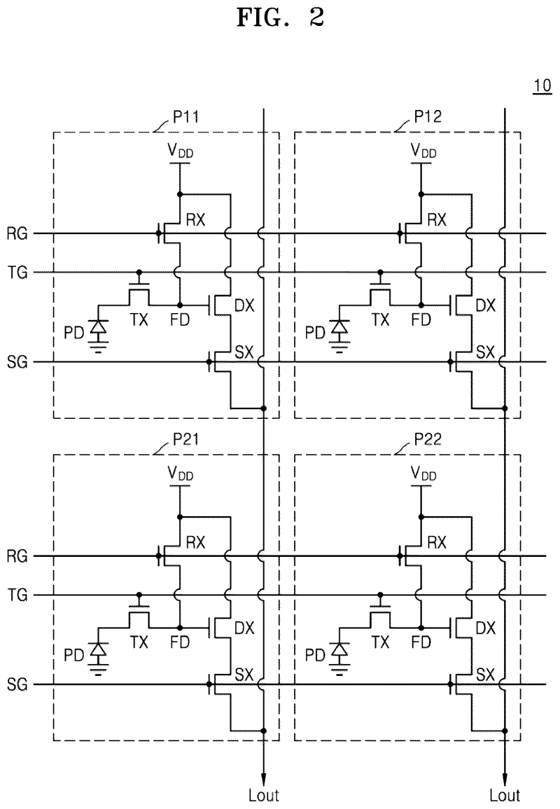

FIG. 2 is a circuit diagram illustrating pixels included in an image sensor according to some example embodiments.

Referring to FIGS. 1 and 2, a pixel array 10 may include a plurality of pixels P11, P12, P21, and P22. The pixels P11, P12, P21, and P22 may be arranged in a matrix form. Although only four pixels P11, P12, P21, and P22 are shown in FIG. 2 for convenience of illustration, a description of these pixels may be similarly applied to each of the plurality of pixels P11 to PMN included in the pixel array 10.

According to some example embodiments, each of the pixels P11, P12, P21, and P22 may include a transfer transistor TX, logic transistors RX, SX, and DX, and a photoelectric converter PD. Here, the logic transistors may include a reset transistor RX, a selection transistor SX, and a drive transistor DX.

The photoelectric converter PD may generate and accumulate photocharges in proportion to the amount of light incident to the photoelectric converter PD from the outside. The photoelectric converter PD may be a light-sensing element made of an organic material or an inorganic material, such as an inorganic photodiode, an organic photodiode, a perovskite photodiode, a phototransistor, a photogate or a pinned photodiode, and an organic photoconductive film.

The transfer transistor TX may transfer charges accumulated in the photoelectric converter PD to the floating diffusion region FD based on the transfer signal TG. The photocharges generated by the photoelectric converter PD may be stored in the floating diffusion region FD. The drive transistor DX may be controlled by the amount of photocharges accumulated in the floating diffusion region FD.

The reset transistor RX may periodically reset charges accumulated in the floating diffusion region FD based on the reset signal RG. A drain electrode of the reset transistor RX may be connected to the floating diffusion region FD, and a source electrode of the reset transistor RX may be connected to a power supply voltage VDD. When the reset transistor RX is turned on, the power supply voltage VDD connected to the source electrode of the reset transistor RX may be transferred to the floating diffusion region FD. Therefore, when the reset transistor RX is turned on, the charges accumulated in the floating diffusion region FD are discharged and the floating diffusion region FD may be reset.

The drive transistor DX may configure a source follower buffer amplifier together with a constant current source outside each of the pixels P11, P12, P21, and P22 and may amplify a potential change in the floating diffusion region FD and output the amplified potential change to the output line Lout.

The selection transistor SX may select pixels P11, P12, P21, and P22 from which to read the value of the photoelectric signal sensed in a row unit based on the selection signal SG. When the selection transistor SX is turned on, the power supply voltage VDD may be transferred to the source electrode of the drive transistor DX.

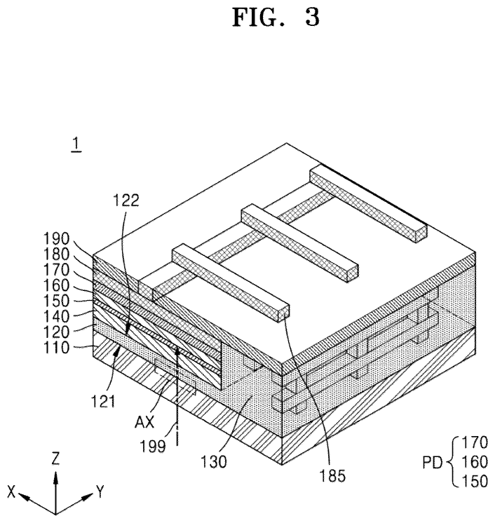

FIG. 3 is a schematic perspective view of an image sensor 1 according to some example embodiments.

Referring to FIG. 3, the image sensor 1 may include an anti-reflection layer 110, a semiconductor substrate 120, a circuit area 130, a doped layer 140, a photoelectric converter PD, a conductive layer 180, an insulating layer 190, and a planarization layer (not shown). The semiconductor substrate 120 may include a first surface 121 and a second surface 122 that face each other. The first surface 121 of the semiconductor substrate 120 may be a front surface of the semiconductor substrate 120, and the second surface 122 of the semiconductor substrate 120 may be a rear surface of the semiconductor substrate 120. The first surface 121 and the second surface 122 of the semiconductor substrate 120 may be polished and smooth. The first surface 121 and the second surface 122 of the semiconductor substrate 120 may be polished to have an infrared transmittance of about 50% or more (e.g., about 50% to about 100%, about 60% to about 100%, about 70% to about 100%, etc.).

The doped layer 140 may be formed from a portion of the semiconductor substrate 120 based on doping the portion (e.g., limited portion of the semiconductor substrate 120 doped with p-type impurities). As a result, the doped layer 140 may include the same material as the semiconductor substrate 120 and may further include a doped impurity (e.g., a p-type impurity, an n-type impurity, or the like), where the doped layer 140 and the semiconductor substrate 120 may be separate portions of a single, unitary piece of material (e.g., where the semiconductor substrate 120 includes none or substantially none of the one or more doped impurities which are included in the doped layer 140). The doped layer 140 may include a p-type impurity which may be boron B. However, the present inventive concepts are not limited thereto. The doped layer 140 may include an n-type impurity which may include at least one of phosphorus (P), arsenic (As), antimony (Sb), or bismuth (Bi). The doped layer 140 may be in contact with the photoelectric converter PD (e.g., based on being in contact with the electron transport layer 150).

Two directions parallel or substantially parallel to the first surface 121 and perpendicular or substantially perpendicular to each other are defined as a first direction (X direction) and a second direction (Y direction), and a direction perpendicular or substantially perpendicular to the first surface 121 is defined as a third direction (Z direction). The first direction, the second direction, and the third direction may be perpendicular or substantially perpendicular to each other.

The anti-reflection layer 110 may be disposed on the first surface 121 of the semiconductor substrate 120. The anti-reflection layer 110 may be a transparent insulating layer based on an oxide film. In some example embodiments, the anti-reflection layer 110 may include hafnium oxide (HfO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), or yttrium oxide (Y₂O₃). The anti-reflection layer 110 may be a single layer made of any of the above-described materials or a multi-layer laminate of the above-described material layers.

A plurality of pixels P11, P12, P13, P14, P21, P22, P23, P24, P31, P32, P33, P34, P41, P42, P43, P44, (hereinafter P11 to P44) may be formed in the semiconductor substrate 120. The plurality of pixels P11 to P44 may be arranged in a matrix form in a plan view. A plurality of photoelectric converters PD may be disposed in (e.g., vertically overlapping) cach of the plurality of pixels P11 to P44. According to some example embodiments, a plurality of pixels P11 to P44 may be disposed at the center of the matrix and dummy pixels may be disposed at the edges of the matrix.

A plurality of active pixels PX may be arranged in the semiconductor substrate 120. For example, in a plan view, a plurality of active pixels PX may be arranged in a matrix form, and a plurality of photoelectric converters may be disposed in each of the plurality of active pixels PX.

The circuit area 130 may be formed inside the semiconductor substrate 120. The circuit area 130 may be spaced apart from the photoelectric converter PD in the first direction and disposed between the insulating layer 190 and the anti-reflection layer 110 (e.g., between the insulating layer 190 and the anti-reflection layer 110 in the third direction). The circuit area 130 may be an area where various types of circuits for controlling a plurality of pixels are formed. For example, the circuit area 130 may include a plurality of transistors, and the plurality of transistors may be driven to provide a constant signal to each photoelectric converter PD or to control an output signal from each photoelectric converter PD. For example, the transistor may configure various types of logic circuits, such as a timing generator, a row decoder, a row driver, a correlated double sampler (CDS), an ADC, a latch, and a column decoder but is not limited to thereto.

According to some example embodiments, the photoelectric converter PD may be formed on the second surface 122 of the semiconductor substrate 120. Gate electrodes (not shown) may be spaced apart from each other on the second surface 122 of the semiconductor substrate 120. The gate electrode may be, for example, any one of the gate electrode of the transfer transistor TX of FIG. 2, the gate electrode of the reset transistor RX, or the gate electrode of the drive transistor DX. Here, the gate electrode is not limited to being disposed on the second surface 122 of the semiconductor substrate 120. For example, the gate electrode may also be buried in the semiconductor substrate 120.

The photoelectric converter PD (e.g., each photoelectric converter PD of the plurality of photoelectric converters PD) may include an electron transport layer 150, an absorption layer 160, and a hole transport layer 170. The electron transport layer 150 may be on the second surface 122 of the semiconductor substrate 120, the absorption layer 160 may be on the electron transport layer 150, and the hole transport layer 170 may be on the absorption layer 160 such that the absorption layer 160 may be between the electron transport layer 150 and the hole transport layer 170. The photoelectric converter PD may be an area for generating an electrical signal from light incident through the first surface 121 of the semiconductor substrate 120. For example, the plurality of photoelectric converters PD may be areas for generating electrical signals from infrared rays incident through the first surface 121 of the semiconductor substrate 120, but the inventive concepts are not limited thereto. By receiving infrared rays through the first surface 121 of the semiconductor substrate 120 and absorbing the infrared rays using the absorption layer 160 of the photoelectric converter PD, the image sensor 1 of the inventive concepts may not include a transparent electrode and a micro lens (e.g., may not include any transparent electrode and may not include any micro lens). In detail, the micro lens may not be included on the first surface 121 of the semiconductor substrate 120 (e.g., the image sensor 1 may not include any micro lens on the first surface 121 of the semiconductor substrate 120), and the transparent electrodes may not be included on the first surface 121 and the second surface 122 of the semiconductor substrate 120 (e.g., the image sensor 1 may not include any transparent electrodes on the first surface 121 and/or the second surface 122 of the semiconductor substrate 120).

The electron transport layer 150 may facilitate the transport of electrons. The electron transport layer 150 may include, for example, one selected from 1,4,5,8-naphthalene-tetracarboxylic dianhydride (NTCDA), bathocuproine (BCP), LiF, Alq₃, Gaq₃, Inq₃, Znq₂, Zn(BTZ)₂, BeBq₂, and combinations thereof but is not limited thereto.

The absorption layer 160 may include a plurality of colloidal quantum dots. The absorption layer 160 may be formed of only the plurality of colloidal quantum dots. In addition, the absorption layer 160 may further include an oxide layer (not shown) on at least one side of the absorption layer 160. One side of the absorption layer 160 may contact the electron transport layer 150 and the other side of the absorption layer 160 may contact the hole transport layer 170. The absorption layer 160 may include at least one of PbS, PbSe, InAs, InGaAs, Ag₂Se, CaTiO₃, CdTe, InP, InSb, PbTe, AlAs, ZnS, ZnSe, ZnTe, CdSe, CdS, or an organic material. When infrared rays are incident on the absorption layer 160 (e.g., incident on the absorption layer 160 through the semiconductor substrate 120 via being incident on the first surface 121 of the semiconductor substrate 120), the absorption layer 160 may absorb the infrared rays to generate photocarriers, that is, movable pairs of electrons and holes. The absorption layer 160 may absorb infrared rays of any one wavelength in a range of about 780 nm to about 3000 nm.

Each quantum dot of the plurality of colloidal quantum dots may include a core unit and a shell unit. The shell unit may completely surround the core unit. The shell unit may have a single shell or a double shell structure. The diameter of each quantum dot may be, for example, less than or equal to about 10 nm (e.g., about 0.01 nm to about 10 nm). An organic ligand may exist on a surface of each of the quantum dots. The organic ligand may include, for example, trioctylphosphne, trioctylamine, trioctylphosphine oxide, etc. When necessary, the organic ligand may be removed. Each of the quantum dots may include a colloidal quantum dot. The core unit may include at least one of CdSe, InP, PbS, PbSe and CdTe. In addition, the shell unit may include at least one of CdS and ZnS. The absorption layer 160 may also include at least one material of a semiconductor including IV group elements such as Si, Ge, and SiGe, a III-V group compound semiconductor, an oxide semiconductor, a nitride semiconductor, an oxynitride semiconductor, etc.

The hole transport layer 170 may facilitate transport of holes therethrough. The hole transport layer 170 may include, for example, one selected poly(3,4-ethylenedioxythiophene):poly (styrenesulfonate) (poly(3,4-ethylenedioxythiophene):poly (styrenesulfonate), PEDOT:PSS), polyarylamine, poly (N-vinylcarbazole), polyaniline, polypyrrole, N,N,N′,N′-tetrakis (4-methoxyphenyl)-benzidine, TPD), 4,4′-bis [N-(1-naphthyl)-N-phenyl-amino] biphenyl (4,4′-bis [N-(1-naphthyl)-N-phenyl-amino] biphenyl, a-NPD), m-MTDATA (4,4′,4″-tris [phenyl (m-tolyl) amino] triphenylamine), 4,4′4″-tris (N-carbazolyl)-triphenylamine (4,4′,4″-tris (N-carbazolyl)-triphenylamine, TCTA), and combinations thereof but is not limited thereto.

The absorption layer 160 may generate excitons by absorbing the infrared rays. In this case, excitons may be separated by the internal electric field between the electron transport layer 150 and the absorption layer 160. Holes and charges generated by the separation of excitons may be extracted by moving to the conductive layer 180 and the doped layer 140.

The conductive layer 180 may include, for example, aluminum (Al), copper (Cu), tungsten (W), cobalt (Co), ruthenium (Ru), silver (Ag), gold (Au), or the like. The conductive layer 180 may be disposed on the hole transport layer 170. The conductive layer 180 may be electrically connected to a plurality of conductive patterns 185.

The plurality of conductive patterns 185 may include, for example, aluminum (Al), copper (Cu), tungsten (W), cobalt (Co), ruthenium (Ru), or the like. Also, the plurality of conductive patterns 185 may include a plurality of stacked wires at different levels (e.g., different distances from the first surface 121 of the semiconductor substrate 120 in the third direction). The conductive layer 180 and the plurality of conductive patterns 185 may provide (e.g., define) a path (e.g., a conductive path) for outputting an electrical signal generated by the photoelectric converter PD. That is, the conductive layer 180 and the plurality of conductive patterns 185 may electrically connect the photoelectric converter PD to the circuit area 130 and thus may establish a conductive path to direct an electrical signal generated by the photoelectric converter PD to the circuit area 130. Any one of the plurality of conductive patterns 185 may be disposed on the insulating layer 190 (e.g., may be exposed from the insulating layer 190 in the third direction) and may correspond to an upper conductive pattern. The upper conductive pattern may extend onto the circuit area 130 on the photoelectric converter PD in the first direction.

The insulating layer 190 may be disposed on the conductive layer 180, and the conductive layer 180 and the plurality of conductive patterns may be protected and insulated by the insulating layer 190. The insulating layer 190 may include silicon oxide, silicon nitride, silicon oxynitride, or the like.

An interlayer insulating layer (not shown) may cover the anti-reflection layer 110. The interlayer insulating layer may include, for example, an oxide film, a nitride film, a low dielectric material, and a resin. The interlayer insulating layer may include the same material as the insulating layer 190. According to some example embodiments, the planarization layer may include a multilayer structure.

In some example embodiments, an image sensor I may have an improved absorption rate with regard to absorption of incident light in an infrared or rear-infrared wavelength region (e.g., infrared rays) based on including colloidal quantum dots in the absorption layer 160 and/or based on including a refraction pattern PA on a first surface 121 of the semiconductor substrate 120, where such inclusions may results in the image sensor 1 being configured to have improved signal-to-noise ratio (e.g., reduced signal noise) and/or improved sensitivity to infrared rays. Additionally, based on the image sensor 1 including an absorption layer 160 that includes colloidal quantum dots (e.g., instead of an infrared light absorbing material of InGaAs or GaAs) may have a reduced production cost and/or reduced unit price, and the absorption layer 160 that includes colloidal quantum dots may be formed using lower-temperature formation processes and/or lower-cost formation processes than processes for forming an absorption layer that includes infrared light absorbing material of InGaAs or GaAs, thereby providing an effective image sensor at lower manufacturing cost and improved productivity of the image sensor.

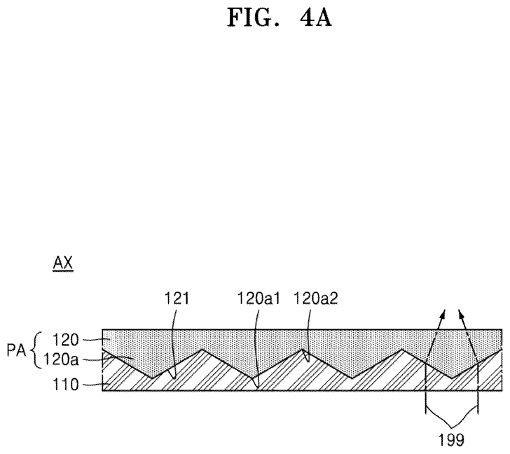

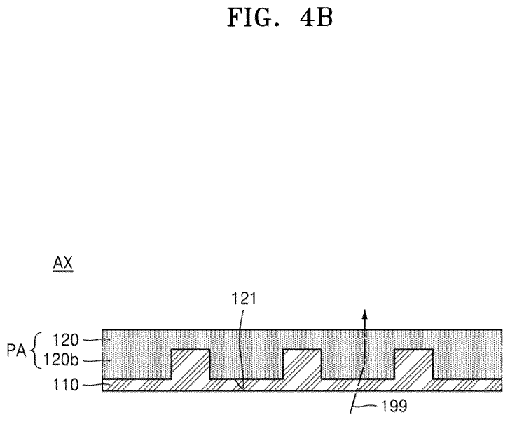

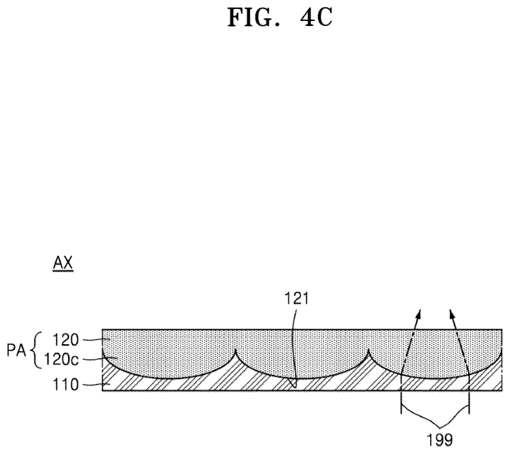

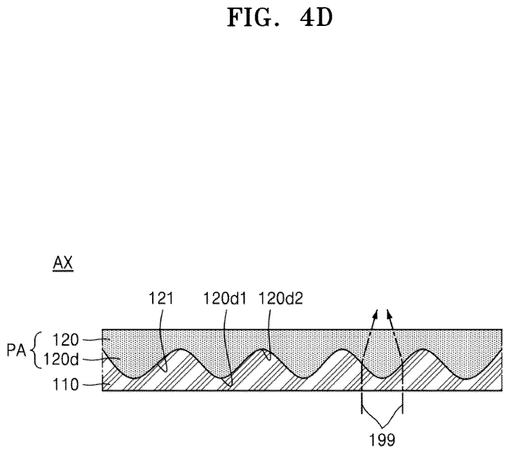

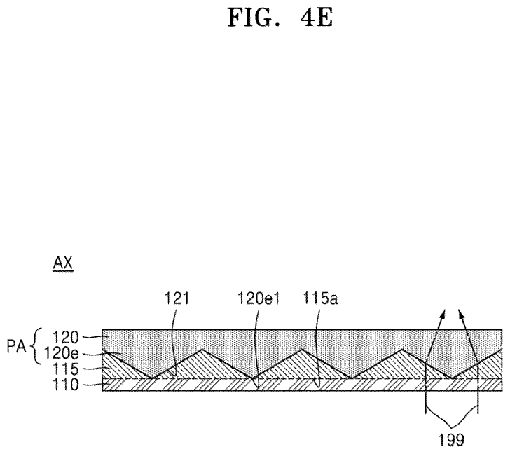

FIGS. 4A, 4B, 4C, 4D, and 4E are enlarged views of area AX shown in FIG. 3 according to some example embodiments. In the following, a description is made with reference to FIG. 3, and descriptions already given in the description of FIG. 3 are briefly described or omitted.

Referring to FIGS. 3, 4A to 4D, the semiconductor substrate 120 may include refraction patterns 120a, 120b, 120c, and 120d formed on the first surface 121 of the semiconductor substrate 120 and contacting the anti-reflection layer 110. As shown, a refraction pattern PA formed on the first surface 121 may be a structure that is formed on the first surface 121 and protrudes from the first surface in the third direction (e.g., in the Z direction towards the anti-reflection layer 110). In some example embodiments, a refraction pattern PA formed on the first surface may be at least partially defined by the first surface 121 of the semiconductor substrate 120, at least partially formed by the first surface 121 of the semiconductor substrate 120, etc., such that the surface of the refraction pattern PA facing and/or in contact with the anti-reflection layer 110 is considered to be the first surface 121 of the semiconductor substrate 120, where the refraction pattern PA may be a portion of the semiconductor substrate 120 (e.g., part of a same unitary piece of material as the remainder of the semiconductor substrate 120), or the like. In some example embodiments, the refraction pattern PA that is formed on the first surface 121 (e.g., refraction patterns 120a, 120b, 120c, and/or 120d). The refraction pattern PA may refract incident light 199 that is incident (e.g., incident on and/or through the semiconductor substrate 120) through the first surface 121 of the semiconductor substrate 120, such that the incident light 199 is refracted through the semiconductor substrate 120 and into the photoelectric converter PD. The first surface 121 of the semiconductor substrate 120 may serve as a micro lens for infrared rays (e.g., to focus, refract, condense, etc. incident light 199 towards the photoelectric converter PD) by forming (e.g., based on at least partially defining) the refraction pattern PA. As a result, an image sensor 1 may be configured to provide improved sensitivity to infrared rays without including a separate micro lens on the first surface 121 of the semiconductor substrate 120, based on the semiconductor substrate 120 including a refraction pattern PA formed on (e.g., at least partially defined by) the first surface 121 of the semiconductor substrate 120 that is configured to refract, condense, focus, etc. incident infrared rays to propagate through the semiconductor substrate 120 and to be incident on the photoelectric converter PD. As a result, the amount of incident infrared rays detected by the photoelectric converter PD may be improved without requiring a separate micro lens structure to be formed on the semiconductor substrate 120, and thus both the performance of the image sensor 1 may be improved and the manufacturing process to manufacture the image sensor 1 may be simplified, so that the costs, production time, and likelihood of process defects may be reduced as a result of such simplification. In detail, the refraction patterns are described below.

Referring to FIGS. 3 and 4A, the refraction pattern 120a of the semiconductor substrate 120 may include a plurality of triangular shapes formed along (e.g., at least partially defined by) the first surface 121 of the semiconductor substrate 120. The plurality of triangular shapes (e.g., triangular projections from the semiconductor substrate 120 toward the anti-reflection layer 110 in the third direction) may include the shape of a sharp mountain toward the anti-reflection layer 110 (e.g., a structure having a vertex 120a1 (e.g., apex) proximate to the anti-reflection layer 110 in the third direction and a trough 120a2 distal to the anti-reflection layer 110 in the third direction. In addition, the plurality of triangular shapes may include a zigzag shape along one or more directions substantially parallel to the first surface 121 (e.g., along the first direction (X direction) and/or the second direction (Y direction)). The plurality of triangular shapes may refract and condense incident light 199, for example so that an amount of incident light 199 that is directed through the semiconductor substrate 120 to be incident upon the absorption layer 160 of the photoelectric converter PD and thus to be detected (e.g., absorbed and photoelectrically converter) by the image sensor 1 is increased, thereby improving sensitivity of the image sensor 1.

Referring to FIGS. 3 and 4B, the refraction pattern 120b of the semiconductor substrate 120 may include a plurality of square shapes and/or rectangular shapes formed along (e.g., at least partially defined by) the first surface 121 of the semiconductor substrate 120. In FIG. 4B, the plurality of quadrangular shapes (e.g., quadrangular projections from the semiconductor substrate 120 toward the anti-reflection layer 110 in the third direction) may have different widths or sizes in the first, second, and/or third directions but are not limited thereto and may be formed along the first surface 121 of the semiconductor substrate 120 to have the same width or size as each other.

Referring to FIGS. 3 and 4C, the refraction pattern 120c of the semiconductor substrate 120 may include a plurality of lens shapes formed along (e.g., at least partially defined by) the first surface 121 of the semiconductor substrate 120. The refraction pattern 120c may include a shape of a convex lens that is convex from the semiconductor substrate 120 toward the anti-reflection layer 110 (e.g., in the third direction). The refraction pattern 120c of the semiconductor substrate 120 may refract incident light incident on the first surface 121 of the semiconductor substrate 120 and condense the incident light into the photoelectric converter PD (e.g., through the semiconductor substrate 120 and into the photoelectric converter PD via the second surface 122 of the semiconductor substrate 120), for example so that an amount of incident light 199 that is directed through the semiconductor substrate 120 to be incident upon the absorption layer 160 of the photoelectric converter PD and thus to be detected (e.g., absorbed and photoelectrically converter) by the image sensor 1 is increased, thereby improving sensitivity of the image sensor 1.

Referring to FIGS. 3 and 4D, the refraction pattern 120d of the semiconductor substrate 120 may include a plurality of wave shapes formed along (e.g., at least partially defined by) the first surface 121 of the semiconductor substrate 120. The plurality of wave shapes may include wave patterns in which vertical levels (e.g., distances in the third direction from the second surface 122 of the semiconductor substrate) of crests 120d1 and valleys 120d2 are constant.

Referring to FIGS. 3 and 4E, in some example embodiments, an interlayer insulating layer 115 may be disposed between the semiconductor substrate 120 and the anti-reflection layer 110. In the interlayer insulating layer 115, a surface 115a in contact with the anti-reflection layer 110 is a horizontal surface (e.g., a surface extending along a plane extending in the first and second directions), and a space between a surface opposite to the surface 115a in contact with the anti-reflection layer 110 and the refraction pattern 120e of the semiconductor substrate 120 may be filled. As shown, the refraction pattern 120e may be in contact with the interlayer insulating layer 115. For example, the interlayer insulating layer 115 may occupy an entire space between the first surface 121 of the semiconductor substrate 120 which at least partially defines the refraction patterns 120e and the anti-reflection layer 110. As shown, in some example embodiments a portion of the refraction pattern 120e having a lowest level (e.g., vertex 120e1) may be coplanar with the surface 115a of the interlayer insulating layer 115. In FIG. 4E, although the case where the refraction pattern 120e has a triangular shape has been illustrated, it is not limited thereto, and similarly in the case of a square shape, a lens shape, or a wave pattern shape, the interlayer insulating layer 115 may be between the semiconductor substrate 120 and the anti-reflection layer 110.

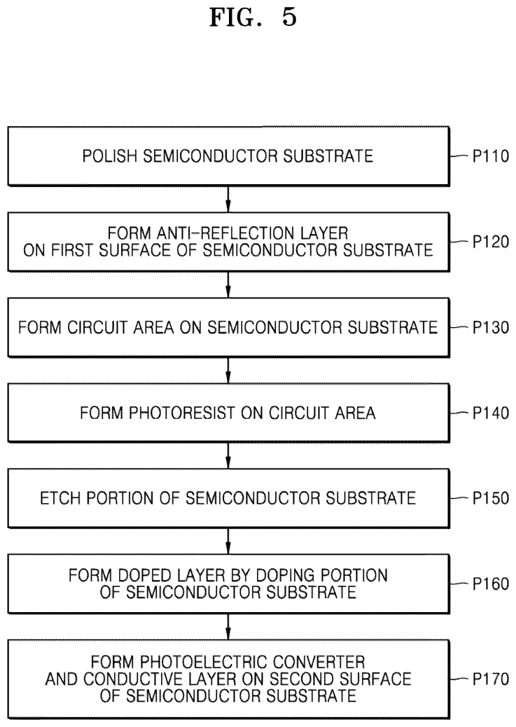

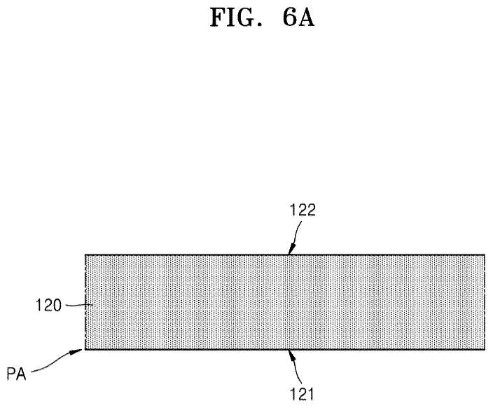

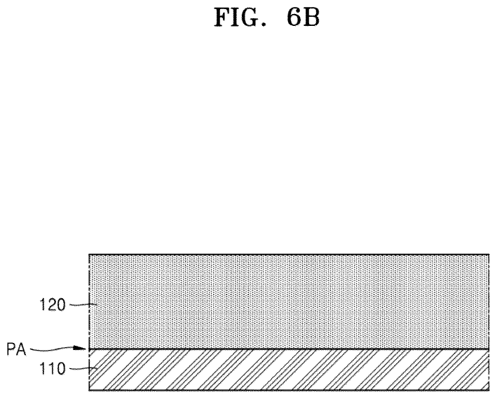

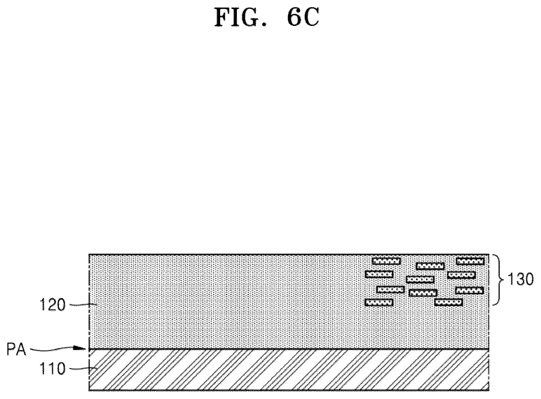

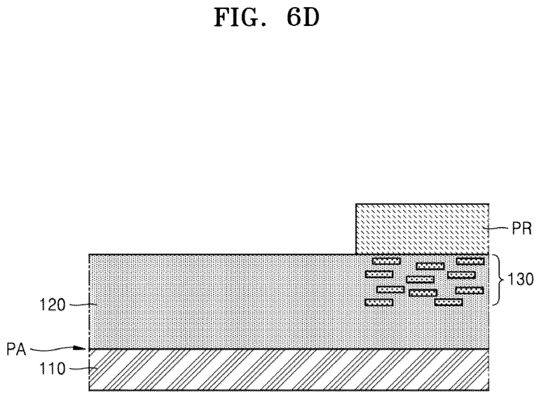

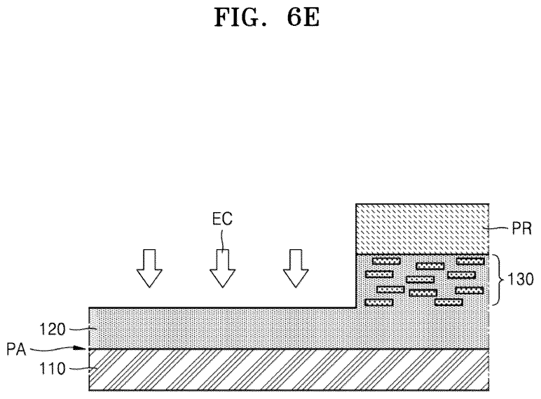

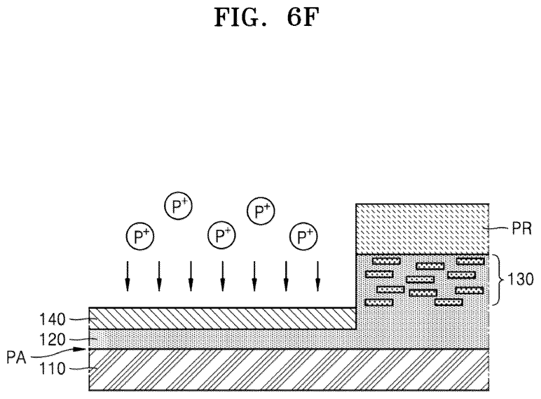

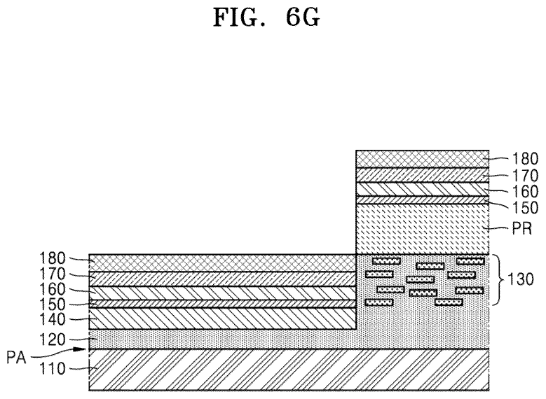

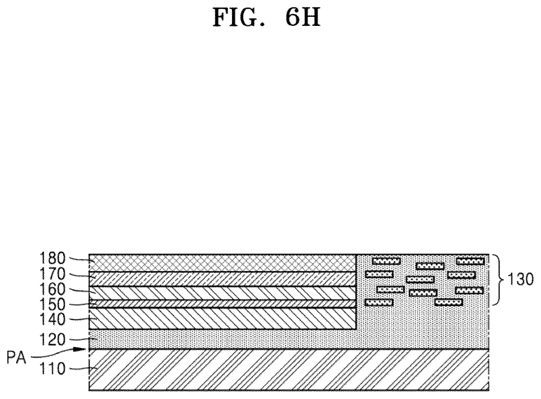

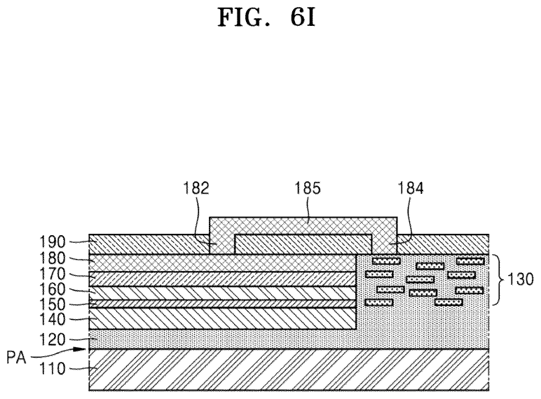

FIG. 5 is a flowchart illustrating a method of manufacturing an image sensor, according to some example embodiments. FIGS. 6A, 6B, 6C, 6D, 6E, 6F, 6G, 6H, and 6I are cross-sectional views illustrating a method of manufacturing an image sensor, according to some example embodiments. In the following, a description is made with reference to FIG. 3, and descriptions already given in the description of FIG. 3 are briefly described or omitted.

Referring to FIGS. 5 and 6A, in process P110 of the manufacturing method of the image sensor 1, according to some example embodiments, first the first surface 121 and the second surface 122 of the semiconductor substrate 120 may be polished to be smooth (e.g., planar or substantially planar). Here, the first surface 121 of the semiconductor substrate 120 and the second surface 122 of the semiconductor substrate 120 may be formed smoothly through a chemical mechanical polish (CMP) process. Here, a refraction pattern PA may be formed on the first surface 121 of the semiconductor substrate 120, subsequent to the polishing, concurrently with the polishing, or prior to the polishing (e.g., based on etching the first surface 121 to form a refraction pattern PA such that the refraction pattern PA may be at least partially defined by the first surface 121 of the semiconductor substrate 120). Subsequently to the refraction pattern PA being formed on the first surface 121 of the semiconductor substrate 120 at least one of the first surface 121 or the second surface 122 of the semiconductor substrate 120 (e.g., at least the second surface 122 of the semiconductor substrate 120) may be planar or substantially planar.

Referring to FIGS. 5 and 6B, in process P120, an anti-reflection layer 110 may be formed on the first surface 121 of the semiconductor substrate 120. Here, infrared rays may be incident on the anti-reflection layer 110 and the first surface 121 of the semiconductor substrate 120. The anti-reflection layer 110 may contact the refraction pattern of the first surface 121 of the semiconductor substrate 120. In addition, in some example embodiments, an interlayer insulating layer (not shown) may be formed between the anti-reflection layer 110 and the semiconductor substrate 120.

Referring to FIGS. 5 and 6C, in process P130, a circuit area 130 may be formed on one side of the semiconductor substrate 120.

Referring to FIGS. 5 and 6D, in process P140, a photoresist PR may be formed on the circuit area 130 through a photoresist process. A material constituting the provided photoresist PR may be sensitive to any one of ultra violet (UV) rays, deep UV (DUV) rays, extreme UV (EUV) rays, excimer laser beams, X-rays, or electrons. Here, the photoresist PR may be provided by a chemical vapor deposition (CVD) method or a spin coating method.

Referring to FIGS. 5 and 6E, in process P150, in order to form a photoelectric converter PD on the semiconductor substrate 120, a portion of the semiconductor substrate 120 may be etched through an etching process. In this case, the photoresist PR is not etched and the circuit area 130 may not be etched.

Referring to FIGS. 5 and 6F, after the etching process, in process P160, a portion of the semiconductor substrate 120 may be doped to form a doped layer 140. In some example embodiments, the doped layer 140 may be formed by doping P-type impurities (e.g., boron).

Referring to FIGS. 5, 6G, and 6H, in process P170, the photoelectric converter PD and a conductive layer 180 may be formed on the doped layer 140. The photoelectric converter PD may include an electron transport layer 150, an absorption layer 160, and a hole transport layer 170. Here, the electron transport layer 150, the absorption layer 160, and the hole transport layer 170 may be sequentially stacked on the second surface 122 of the semiconductor substrate 120. The conductive layer 180 may be formed on the hole transport layer 170. Next, the electron transport layer 150, the absorption layer 160, the hole transport layer 170, and the conductive layer 180 formed on the circuit area 130 may be removed by removing the photoresist PR.

Referring to FIGS. 5 and 6I, a plurality of conductive patterns 182, 184, and 185 and an insulating layer 190 may be formed on the conductive layer 180. Through this manufacturing method, the image sensor 1 of FIG. 3 may be formed.

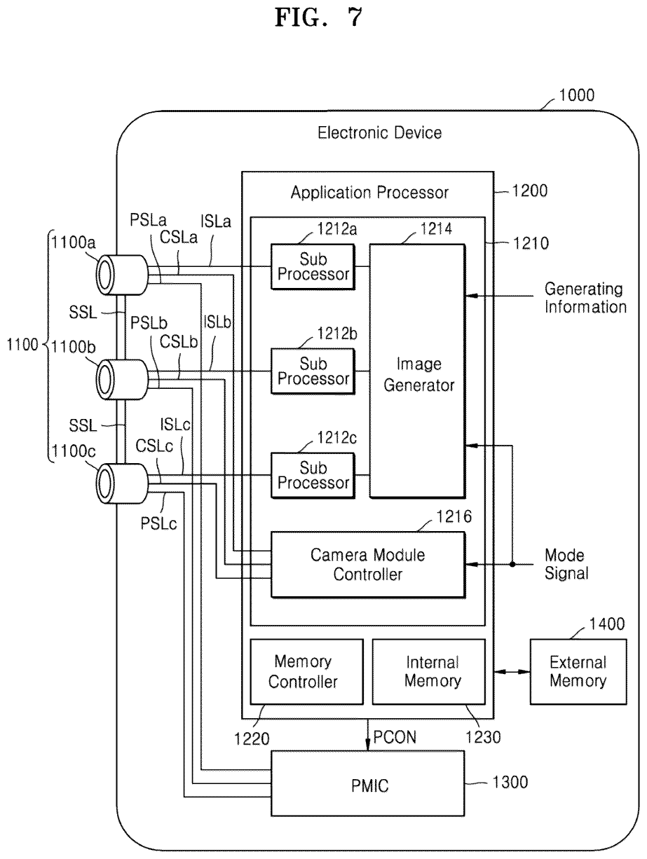

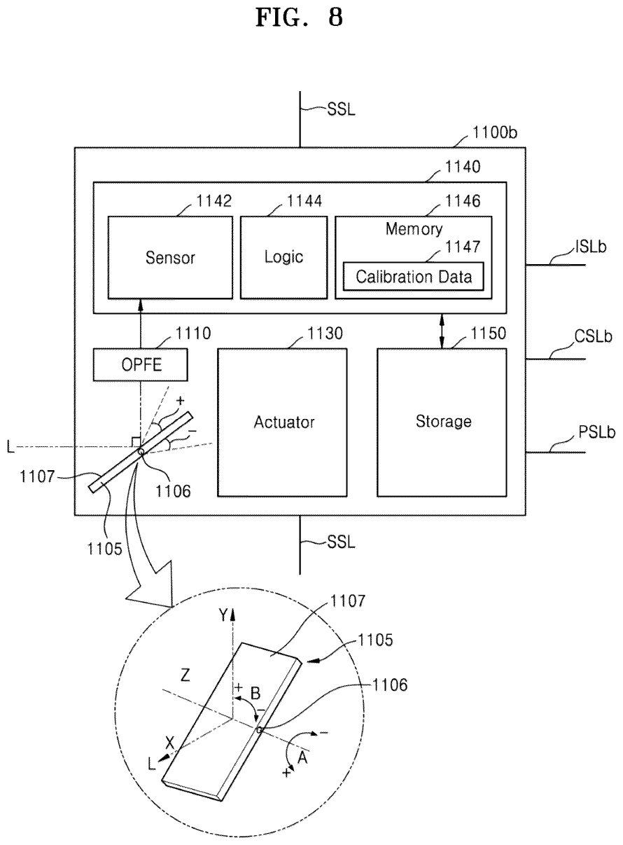

FIG. 7 is a block diagram of an electronic device including a multi-camera module according to some example embodiments, and FIG. 8 is a detailed block diagram of the camera module of FIG. 7 according to some example embodiments.

Referring to FIG. 7, an electronic device 1000 may include a camera module group 1100, an application processor 1200, a power management integrated circuit (PMIC) 1300, and an external memory 1400.

The camera module group 1100 may include a plurality of camera modules 1100a, 1100b, and 1100c. Although the drawing shows some example embodiments in which three camera modules 1100a, 1100b, and 1100c are disposed, the example embodiments are not limited thereto. In some example embodiments, the camera module group 1100 may include only two camera modules or may be modified to include n camera modules (where n is a natural number equal to or greater than 4).

Referring to FIG. 8, the camera module 1100b may include a prism 1105, an optical path folding element (OPFE) 1110, an actuator 1130, an image sensing device 1140, and a storage unit 1150.

Here, although the detailed configuration of the camera module 1100b is described in more detail, the following description may be equally applied to the other camera modules 1100a and 1100c according to some example embodiments.

The prism 1105 may include a reflective surface 1107 of a light reflective material to transform the path of light L incident from the outside.

In some example embodiments, the prism 1105 may change the path of light L incident in a first direction (X direction) to a second direction (Y direction) perpendicular to the first direction (X direction). In addition, the prism 1105 may rotate the reflective surface 1107 of the light reflecting material in the A direction around a central axis 1106 or rotate the central axis 1106 in the B direction to change the path of the light L incident in the first direction (X direction) to a second direction (Y direction) perpendicular to the first direction. At this time, the OPFE 1110 may also move in a third direction (Z direction) perpendicular to the first direction (X direction) and the second direction (Y direction).

In some example embodiments, as shown, the maximum rotation angle of the prism 1105 in the A direction may be 15° or less in the positive (+) A direction and greater than 15° in the negative (−) A direction, but the example embodiments are not limited thereto.

In some example embodiments, the prism 1105 may move around 20° in the positive (+) or negative (−) B direction, or between 10° and 20°, or between 15° and 20°, where the moving angle may move at the same angle in the positive (+) or negative (−) direction B, or may move to an almost similar angle within a range of about 1°.

In some example embodiments, the prism 1105 may move the reflective surface 1107 of the light reflective material in a third direction (Z direction) parallel to the extension direction of the central axis 1106.

The OPFE 1110 may include, for example, optical lenses composed of m groups (where m is a natural number). The m lenses may move in the second direction (Y direction) to change the optical zoom ratio of the camera module 1100b. For example, when the basic optical zoom magnification of the camera module 1100b is Z, when m optical lenses included in the OPFE 1110 are moved, the optical zoom magnification of the camera module 1100b may be changed to 3Z, 5Z, or 7Z or more optical zoom magnification.

The actuator 1130 may move the OPFE 1110 or the optical lens to a specific position. For example, the actuator 1130 may adjust the position of the optical lens so that the image sensor 1142 is at the focal length of the optical lens for accurate sensing.

The image sensing device 1140 may include an image sensor 1142, a control logic 1144, and a memory 1146. The image sensor 1142 may sense an image of a sensing target using light L provided through an optical lens. The control logic 1144 may control the overall operation of the camera module 1100b. For example, the control logic 1144 may control the operation of the camera module 1100b depending on a control signal provided through a control signal line CSLb.

The memory 1146 may store information required for operation of the camera module 1100b, such as calibration data 1147. The calibration data 1147 may include information necessary for the camera module 1100b to generate image data using light L provided from the outside. The calibration data 1147 may include, for example, information about a degree of rotation, information about a focal length, information about an optical axis, and the like, as described above. When the camera module 1100b is implemented in the form of a multi-state camera of which the focal length changes depending on the position of an optical lens, the calibration data 1147 may include a focal distance value for each position (or state) of the optical lens and information related to auto focusing.

The storage unit 1150 may store image data sensed through the image sensor 1142. The storage unit 1150 (also referred to as a storage device, memory, external storage, etc.) may be disposed outside the image sensing device 1140 and may be implemented in a stacked form with a sensor chip constituting the image sensing device 1140. In some example embodiments, the storage unit 1150 may be implemented as electrically erasable programmable read-only memory (EEPROM), but example embodiments are not limited thereto.

Referring to FIGS. 7 and 8 together, in some example embodiments, each of the plurality of camera modules 1100a, 1100b, and 1100c may include an actuator 1130. Accordingly, each of the plurality of camera modules 1100a, 1100b, and 1100c may include the same or different calibration data 1147 based on the operation of the actuator 1130 included therein.

In some example embodiments, one of the plurality of camera modules 1100a, 1100b, or 1100c (for example, 1100b) may be a camera module in the form of a folded lens including the prism 1105 and the OPFE 1110 described above, and the other camera modules (e.g., 1100a and 1100c) may be vertical camera modules that do not include the prism 1105 and the OPFE 1110, but example embodiments are not limited thereto.

In some example embodiments, one camera module (e.g., 1100c) among the plurality of camera modules 1100a, 1100b, and 1100c may be, for example, a vertical type depth camera that extracts depth information using infrared ray (IR). In this case, the application processor 1200 may generate a 3D depth image by merging image data provided from the depth camera with image data provided from another camera module (e.g., 1100a or 1100b).

In some example embodiments, among the plurality of camera modules 1100a, 1100b, and 1100c, at least two camera modules (e.g., 1100a and 1100b) may have different fields of view. In this case, for example, optical lenses of at least two camera modules (e.g., 1100a and 1100b) among the plurality of camera modules 1100a, 1100b, and 1100c may be different from each other but are not limited thereto.

In addition, in some example embodiments, the field of view of each of the plurality of camera modules 1100a, 1100b, and 1100c may be different from each other. In this case, optical lenses included in each of the plurality of camera modules 1100a, 1100b, and 1100c may also be different from each other but are not limited thereto.

In some example embodiments, each of the plurality of camera modules 1100a, 1100b, and 1100c may be disposed physically separated from each other. That is, instead of dividing and using the sensing area of one image sensor 1142 by a plurality of camera modules 1100a, 1100b, and 1100c, an independent image sensor 1142 may be disposed inside each of the plurality of camera modules 1100a, 1100b, and 1100c.

Referring back to FIG. 7, the application processor 1200 may include an image processing device 1210, a memory controller 1220, and an internal memory 1230. The application processor 1200 may be implemented separately from the plurality of camera modules 1100a, 1100b, and 1100c. For example, the application processor 1200 and the plurality of camera modules 1100a, 1100b, and 1100c may be separated from each other and implemented as separate semiconductor chips.

The image processing device 1210 may include a plurality of sub image processors 1212a, 1212b, and 1212c, an image generator 1214, and a camera module controller 1216.

The image processing device 1210 may include a plurality of sub image processors 1212a, 1212b, and 1212c, the number of which corresponds to the number of camera modules (e.g. the camera modules 1100a, 1100b, and 1100c).

Image data generated by cach camera module 1100a, 1100b, and 1100c may be provided to a corresponding sub image processor 1212a, 1212b, and 1212c through separate image signal lines ISLa, ISLb, and ISLc. For example, image data generated by the camera module 1100a may be provided to the sub image processor 1212a through the image signal line ISLa, image data generated by the camera module 1100b may be provided to the sub image processor 1212b through the image signal line ISLb, and image data generated by the camera module 1100c may be provided to the sub image processor 1212c through the image signal line ISLc. Such image data transmission may be performed using, for example, a camera serial interface (CSI) based on mobile industry processor interface (MIPI), but example embodiments are not limited thereto.

On the other hand, in some example embodiments, one sub image processor may be arranged to correspond to a plurality of camera modules. For example, the sub image processor 1212a and the sub image processor 1212c are not implemented separately from each other as shown but may be integrated and implemented as one sub image processor. In addition, the image data provided from the camera modules 1100a and 1100c may be selected through a selection element (e.g., a multiplexer) and then provided to the integrated sub image processor.

Image data provided to each of the sub image processors 1212a, 1212b, and 1212c may be provided to the image generator 1214. The image generator 1214 may generate an output image using image data provided by each of the sub image processors 1212a, 1212b, and 1212c based on image generating information or a mode signal.

In detail, the image generator 1214 may generate the output image by merging at least some of image data generated by camera modules 1100a, 1100b, and 1100c having different fields of view based on image generation information or a mode signal. In addition, the image generator 1214 may generate the output image by selecting one of image data generated by the camera modules 1100a, 1100b, or 1100c having different fields of view based on image generation information or a mode signal.

In some example embodiments, the image generation information may include a zoom signal or a zoom factor. In addition, in some example embodiments, the mode signal may be, for example, a signal based on a mode selected by a user.

When the image generation information is a zoom signal or a zoom factor and each of the camera modules 1100a, 1100b, and 1100c has different fields of view, the image generator 1214 may perform different operations based on the type of zoom signal. For example, when the zoom signal is a first signal, after merging the image data output from the camera module 1100a with the image data output from the camera module 1100c, an output image may be generated using the merged image signal and image data output from the camera module 1100b not used for merging. When the zoom signal is a second signal different from the first signal, the image generator 1214 may generate an output image by selecting any one of image data output from each of the camera modules 1100a, 1100b, and 1100c without performing such image data merging. However, the example embodiments are not limited thereto, and a method of processing image data may be modified and implemented as needed.

In some example embodiments, the image generator 1214 may generate merged image data having an increased dynamic range by receiving a plurality of image data having different exposure times from at least one of a plurality of sub image processors 1212a, 1212b, or 1212c and performing HDR processing on the plurality of image data.

The camera module controller 1216 may provide control signals to each of the camera modules 1100a, 1100b, and 1100c. The control signals generated by the camera module controller 1216 may be provided to corresponding camera modules 1100a, 1100b, and 1100c through separate control signal lines CSLa, CSLb, and CSLc.

Any one of the plurality of camera modules 1100a, 1100b, or 1100c may be designated as a master camera module (e.g., 1100b) based on image generation information including a zoom signal or a mode signal and the other camera modules (e.g., 1100a and 1100c) may be designated as slave cameras. Such information may be included in a control signal and provided to corresponding camera modules 1100a, 1100b, and 1100c through separate control signal lines CSLa, CSLb, and CSLc.

Camera modules operating as a master or a slave may be changed based on a zoom factor or an operation mode signal. For example, when the field of view of the camera module 1100a is wider than that of the camera module 1100b and the zoom factor indicates a low zoom magnification, the camera module 1100b may operate as a master and the camera module 1100a may operate as a slave. Conversely, when the zoom factor indicates a high zoom magnification, the camera module 1100a may operate as a master and the camera module 1100b may operate as a slave.

In some example embodiments, the control signal provided from the camera module controller 1216 to each of the camera modules 1100a, 1100b, and 1100c may include a sync enable signal. For example, when the camera module 1100b is a master camera and the camera modules 1100a and 1100c are slave cameras, the camera module controller 1216 may transmit the sync enable signal to the camera module 1100b. The camera module 1100b receiving the sync enable signal may generate a sync signal based on the provided sync enable signal and may provide the generated sync signal to the camera modules 1100a and 1100c through the sync signal line SSL. The camera module 1100b and the camera modules 1100a and 1100c may transmit image data to the application processor 1200 in synchronization with the sync signal.

In some example embodiments, the control signal provided from the camera module controller 1216 to the plurality of camera modules 1100a, 1100b, and 1100c may include mode information depending on the mode signal. Based on the mode information, the plurality of camera modules 1100a, 1100b, and 1100c may operate in a first operation mode and a second operation mode in relation to sensing speed.

The plurality of camera modules 1100a, 1100b, and 1100c may generate an image signal at a first rate (e.g., generate an image signal of the first frame rate) in the first operation mode, encode the image signal at a second rate that is higher than the first rate (e.g., encode the image signal having a second frame rate that is higher than the first frame rate), and transmit the encoded image signal to the application processor 1200.

The application processor 1200 may store the received image signal, in other words, the encoded image signal, in the internal memory 1230 or the external memory 1400 external to the application processor 1200, read and decode the encoded image signal from the internal memory 1230 or the external memory 1400, and display image data generated based on the decoded image signal. For example, a corresponding sub-processor among the plurality of sub image processors 1212a, 1212b, and 1212c of the image processing device 1210 may perform decoding and may also perform image processing on the decoded image signal.

The plurality of camera modules 1100a, 1100b, and 1100c may generate image signals at a third rate that is lower than the first rate (e.g., generate an image signal having a third frame rate that is lower than the first frame rate) in the second operation mode and transmit the image signals to the application processor 1200. The image signal provided to the application processor 1200 may be an unencoded signal. The application processor 1200 may perform image processing on a received image signal or store the image signal in the internal memory 1230 or the external memory 1400.

The PMIC 1300 may supply power, for example, a power supply voltage to each of the plurality of camera modules 1100a, 1100b, and 1100c. For example, under the control of the application processor 1200, the PMIC 1300 may supply first power to the camera module 1100a through the power signal line PSLa, supply second power to the camera module 1100b through the power signal line PSLb, and supply third power to the camera module 1100c through the power signal line PSLc.

The PMIC 1300 may generate power corresponding to each of the plurality of camera modules 1100a, 1100b, and 1100c in response to a power control signal PCON from the application processor 1200 and may also adjust the level of the power. The power control signal PCON may include a power adjustment signal for each operation mode of the plurality of camera modules 1100a, 1100b, and 1100c. For example, the operation mode may include a low power mode, and in this case, the power control signal PCON may include information about the camera module operating in the low power mode and the set power level. Levels of the pieces of power provided to each of the plurality of camera modules 1100a, 1100b, and 1100c may be equal to each other or different from each other. In addition, the level of power may be changed dynamically.

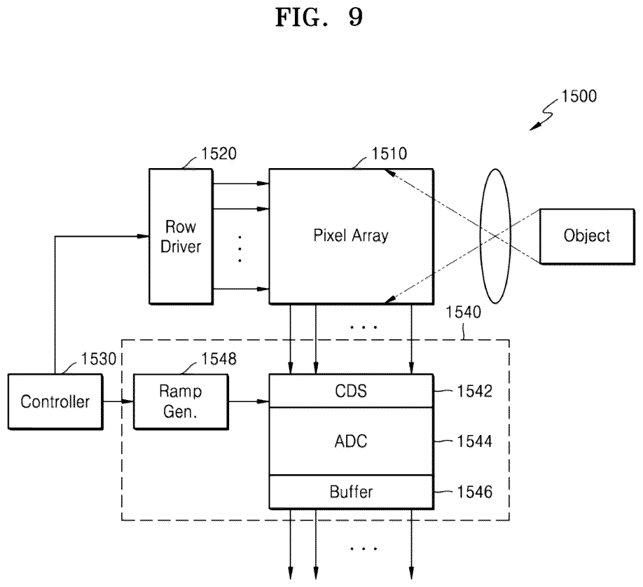

FIG. 9 is a block diagram illustrating the configuration of an image sensor according to some example embodiments.

Referring to FIG. 9, an image sensor 1500 may include a pixel array 1510, a controller 1530, a row driver 1520, and a pixel signal processor 1540.

The image sensor 1500 may include the image sensor 1 described above. The pixel array 1510 may include a plurality of unit pixels that are two-dimensionally arranged, and each unit pixel may include a photoelectric converter. The photoelectric converter may absorb light to generate photocharges, and an electrical signal (output voltage) depending on the generated photocharges may be provided to the pixel signal processor 1540 through a vertical signal line.

Unit pixels included in the pixel array 1510 may provide output voltages one at a time in units of rows, and accordingly, unit pixels of one row of the pixel array 1510 may be simultaneously activated by a selection signal output from the row driver 1520. A unit pixel of the selected row may provide an output voltage depending on absorbed light to an output line of a corresponding column.

The controller 1530 may control the row driver 1520 so that the pixel array 1510 absorbs light to accumulate photocharges or temporarily stores the accumulated photocharges and outputs an electrical signal depending on the stored photocharges to the outside of the pixel array 1510. In addition, the controller 1530 may control the pixel signal processor 1540 to measure an output voltage provided by the pixel array 1510.

The pixel signal processor 1540 may include a correlated double sampler 1542, an analog-to-digital converter 1544, and a buffer 1546. The correlated double sampler 1542 may sample and hold the output voltage provided by the pixel array 1510.

The correlated double sampler 1542 may sample a specific noise level and a level based on the generated output voltage, respectively, and output a level corresponding to a difference between the sampled levels. In addition, the correlated double sampler 1542 may receive the ramp signals generated by the ramp signal generator 1548, compare the received ramp signals with cach other, and output a comparison result.

The analog-to-digital converter 1544 may convert an analog signal corresponding to a level received from the correlated double sampler 1542 into a digital signal. The buffer 1546 may latch the digital signal, and the latched signal may be sequentially output to the outside of the image sensor 1500 and transferred to an image processor (not shown).

As described herein, any devices, systems, modules, portions, units, controllers, circuits, and/or portions thereof according to any of the example embodiments, and/or any portions thereof (including, without limitation, the image sensor 1, the pixel array 10, the row driver 20, the ADC circuit 30, the timing controller 40, the image signal processor 50, the processor 60, the electronic device 1000, the application processor 1200, the image processing device 1210, the sub image processors 1212a, 1212b, and 1212c, the image generator 1214, the camera module group 1100, the camera modules 1100a, 1100b, and 1100c, the camera module controller 1216, the memory controller 1220, the internal memory 1230, the PMIC 1300, the external memory 1400, the image sensing device 1140, the image sensor 1142, the control logic 1144, the memory 1146, the calibration data 1147, the OPFE 1110, the actuator 1130, the storage unit 1150, the image sensor 1500, the pixel array 1510, the controller 1530, the row driver 1520, the pixel signal processor 1540, the ramp signal generator 1548, the correlated double sampler 1542, the analog-to-digital converter 1544, the buffer 1546, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the memories described herein may be a non-transitory computer readable medium and may store a program of instructions. Any of the memories described herein may be a nonvolatile memory, such as a flash memory, a phase-change random access memory (PRAM), a magneto-resistive RAM (MRAM), a resistive RAM (ReRAM), or a ferro-electric RAM (FRAM), or a volatile memory, such as a static RAM (SRAM), a dynamic RAM (DRAM), or a synchronous DRAM (SDRAM).

While the inventive concepts have been particularly shown and described with reference to some example embodiments thereof, it will be understood that various changes in form and details may be made therein without departing from the spirit and scope of the following claims.

What is claimed is:

1. An image sensor, comprising:
a semiconductor substrate including a first surface and a second surface opposite to the first surface;
an anti-reflection layer on the first surface of the semiconductor substrate; and
a photoelectric converter configured to absorb incident light incident through the semiconductor substrate and photoelectrically convert the incident light,
wherein the semiconductor substrate includes a refraction pattern on the first surface of the semiconductor substrate, the refraction pattern configured to refract the incident light.

2. The image sensor of claim 1, wherein the photoelectric converter includes at least one of PbS, PbSe, InAs, InGaAs, AgSe, or CaTiO.

3. The image sensor of claim 1, wherein
the refraction pattern of the semiconductor substrate is in contact with the anti-reflection layer, and
the refraction pattern of the semiconductor substrate includes any one of a triangular shape, a square shape, a lens shape, or a wave pattern shape.

4. The image sensor of claim 1, further comprising:
an interlayer insulating layer between the semiconductor substrate and the anti-reflection layer,
wherein the refraction pattern of the semiconductor substrate is in contact with the interlayer insulating layer.

5. The image sensor of claim 1, further comprising:
a conductive layer on the photoelectric converter;
a plurality of conductive patterns configured to define a conductive path to output an electrical signal generated by the photoelectric converter; and
an insulating layer covering the plurality of conductive patterns.

6. The image sensor of claim 5, wherein the semiconductor substrate includes a circuit area spaced apart from the photoelectric converter in a first direction and between the insulating layer and the anti-reflection layer.

7. The image sensor of claim 6, wherein
the plurality of conductive patterns includes an upper conductive pattern, and
the upper conductive pattern extends from the photoelectric converter onto the circuit area in the first direction.

8. The image sensor of claim 1, wherein the semiconductor substrate includes a doped layer that is in contact with the photoelectric converter and includes P-type impurities.

9. The image sensor of claim 1, wherein the photoelectric converter comprises:
an electron transport layer on the second surface of the semiconductor substrate;
an absorption layer on the electron transport layer; and
a hole transport layer on the absorption layer.

10. The image sensor of claim 1, wherein the image sensor does not include any micro lens on the first surface of the semiconductor substrate.

11. An image sensor, comprising:
a semiconductor substrate including a first surface and a second surface opposite to the first surface;
an anti-reflection layer disposed on the first surface of the semiconductor substrate;
an interlayer insulating layer between the semiconductor substrate and the anti-reflection layer; and
a photoelectric converter configured to absorb incident light incident through the semiconductor substrate and photoelectrically convert the incident light,
wherein the photoelectric converter includes
an electron transport layer on the second surface of the semiconductor substrate,
an absorption layer on the electron transport layer, and
a hole transport layer on the absorption layer,
wherein the semiconductor substrate includes a refraction pattern on the first surface of the semiconductor substrate, the refraction pattern contacting the interlayer insulating layer.

12. The image sensor of claim 11, further comprising:
a conductive layer on the hole transport layer;
a plurality of conductive patterns configured to define a conductive path to output an electrical signal generated by the photoelectric converter; and
an insulating layer partially covering the plurality of conductive patterns,
wherein the plurality of conductive patterns includes at least one of Al, Ag, Cu, or Au.

13. The image sensor of claim 11, wherein
the image sensor does not include any micro lens on the first surface of the semiconductor substrate, and
the image sensor does not include any transparent electrode on the first surface or the second surface of the semiconductor substrate.

14. The image sensor of claim 11, wherein
the absorption layer includes at least one of PbS, PbSe, InAs, InGaAs, AgSe, or CaTiO, and
the absorption layer is configured to absorb infrared rays incident on the first surface of the semiconductor substrate.

15. The image sensor of claim 11, wherein the refraction pattern includes any one of a triangular shape, a square shape, a lens shape, or a wave pattern shape.

16. The image sensor of claim 11, wherein at least the second surface of the semiconductor substrate is planar.

17. An image sensor, comprising:
a semiconductor substrate including a first surface and a second surface opposite to the first surface;
an anti-reflection layer on the first surface of the semiconductor substrate;
an interlayer insulating layer between the semiconductor substrate and the anti-reflection layer; and
a photoelectric converter configured to absorb incident light incident through the semiconductor substrate and photoelectrically convert the incident light,
wherein the photoelectric converter includes
an electron transport layer on the second surface of the semiconductor substrate,
an absorption layer on the electron transport layer, and
a hole transport layer on the absorption layer,
wherein the absorption layer is configured to absorb infrared rays incident on the first surface of the semiconductor substrate, and the absorption layer includes at least one of PbS, PbSe, InAs, InGaAs, AgSe, or CaTiO,
wherein the semiconductor substrate includes a refraction pattern on the first surface of the semiconductor substrate and in contact with the interlayer insulating layer, and
wherein the refraction pattern includes any one of a triangular shape, a square shape, a lens shape, or a wave pattern shape.

18. The image sensor of claim 17, wherein
the image sensor further includes
a conductive layer on the hole transport layer,
a plurality of conductive patterns configured to define a conductive path to output an electrical signal generated by the photoelectric converter, and
an insulating layer partially covering the plurality of conductive patterns,
the semiconductor substrate includes a circuit area spaced apart from the photoelectric converter in a first direction and between the insulating layer and the anti-reflection layer, and
the plurality of conductive patterns includes at least one of Al, Ag, Cu, or Au,
the plurality of conductive patterns includes an upper conductive pattern, and
the upper conductive pattern extends from the photoelectric converter onto the circuit area in the first direction.

19. The image sensor of claim 17, wherein the absorption layer is configured to absorb infrared rays of any one wavelength in a range of about 780 nm to about 3000 nm.

20. The image sensor of claim 17, wherein
the image sensor does not include any micro lens on the first surface of the semiconductor substrate,
the image sensor does not include any transparent electrode on the first surface or the second surface of the semiconductor substrate, and
at least the second surface of the semiconductor substrate is planar.
